(19) United States
(12) Patent Application Publication
(10) Pub. No.: US 2007/0279257 A1
(43) Pub. Date: Dec. 6, 2007

(54) HAND-HELD DEVICE WITH CHARACTER INPUT ROTARY WHEEL

(75) Inventors: Chin-Feng Chen, Shenzhen (CN); Tay-Yang Lin, Shenzhen (CN); Xiao-Guang Li, Shenzhen (CN); Te-Yao Yeh, Shenzhen (CN); Kuan-Hong Hsieh, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/562,966

(22) Filed: Nov. 22, 2006

(30) Foreign Application Priority Data
May 19, 2006 (CN) 200610060753.7

(51) Int. Cl. H03K 17/94

(52) U.S. Cl. 341/35

(57) ABSTRACT

A hand-held device is provided. The hand-held device includes a rotary wheel, a plurality of switches, a plurality of character regions corresponding to the switches, and a controller. The rotary wheel has a plurality of positioning inputs. Each character region comprises a plurality of icons corresponding to the positioning inputs, wherein each icon comprises a character. The controller is responsive to operations on the rotary wheel and the switch, and input a corresponding character. The above-mentioned rotary wheel can replace keyboard in the hand-held device.

### BACKGROUND OF THE INVENTION

1. Field of the Invention

The present invention relates to a hand-held device, particularly to a hand-held device with a character input rotary wheel.

2. Description of Related Art

Hand-held devices, for example, mobile phones and PDAs, usually adopts a keypad to input characters. The keypad typically has fewer keys than a QWERTY keyboard. Furthermore, the key's size is smaller than a key's size of a normal keyboard. A user usually needs to operate keys a plurality of times to input one character. It is uncomfortable to operate small sized keys.

Rotary wheels are used as input apparatus in hand-held devices. For example, U.S. patent application Ser. No. 10/259,159, published May 22, 2003, entitled “Method and apparatus for use of rotational user inputs,” discloses a media player. The media player includes a display screen and an input device. The display screen displays media items. User rotates the input device to select a media item. U.S. Pat. No. 6,842,169, issued October 19, entitled “Hand-held electronic device with multiple input mode thumbwheel,” it discloses a hand-held electronic device. The electronic device includes a thumbwheel as an auxiliary input device. Rotary wheels are used to select menu items, move cursor, but are unable or inconvenient to use as character input device.

Therefore what is needed is a hand-held device with a character input rotary wheel.

### SUMMARY OF THE INVENTION

A hand-held device is disclosed. The hand-held device includes a rotary wheel, a plurality of switches, a plurality of character regions corresponding to the switches, and a controller. The rotary wheel has a plurality of positioning inputs. Each character region comprises a plurality of icons corresponding to the positioning inputs, wherein each icon comprises a character. The controller is responsive to operations on the rotary wheel and the switch, and input a corresponding character.

Another kind of hand-held device is disclosed. The hand-held device includes a rotary wheel, a plurality of switches, an encoder, a memory, and a controller. The rotary wheel has a plurality of positioning inputs. The encoder is responsive to operations on the rotary wheel and outputs positioning codes. The memory stores a plurality of input modes corresponding to the switches, wherein each input mode includes a plurality of characters corresponding to the positioning codes. The controller is responsive to operations on the rotary wheel and the switch, and selects a corresponding character from the memory and inputs it.

Further features will be described or will become apparent in the course of the following detailed description when read in conjunction with the attached drawings, in which:

### BRIEF DESCRIPTION OF THE DRAWINGS

FIG. 1 is a schematic, front view of a hand-held device with a character input rotary wheel according to a first preferred embodiment of the present invention;

FIG. 2 is a schematic diagram of a hardware infrastructure of the hand-held device of FIG. 1; and

FIG. 3 is a schematic, front view of a hand-held device with a character input rotary wheel according to a second preferred embodiment of the present invention.

### DETAILED DESCRIPTION OF THE INVENTION

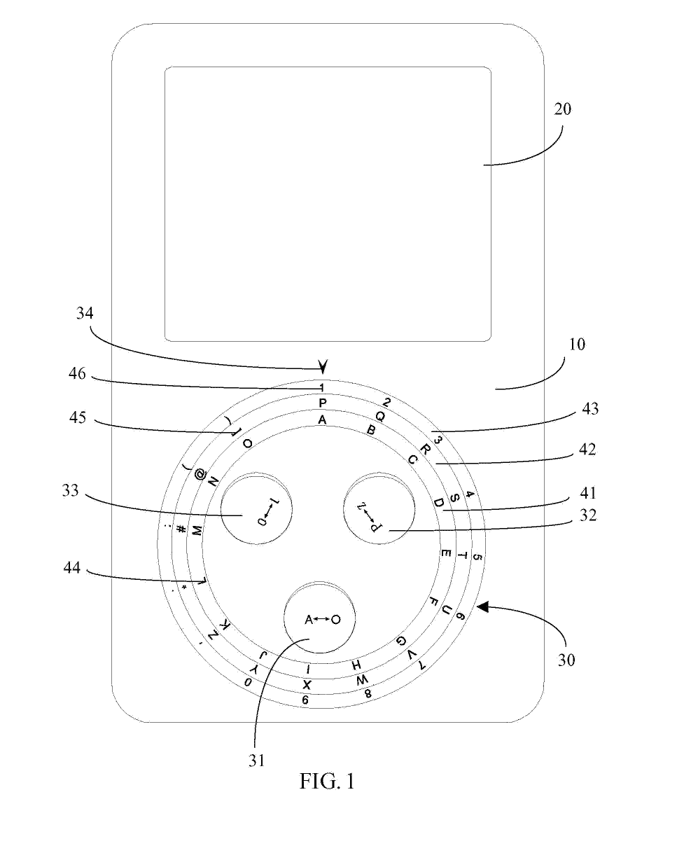

Referring to FIG. 1, a hand-held device of a first preferred embodiment according to the present invention is disclosed. The hand-held device 10 includes a display 20 and a rotary wheel 30. The rotary wheel 30 has fifteen positioning inputs and three character regions 41, 42, 43 thereon. The character regions 41, 42, 43 each have fifteen icons 44, 45, 46 corresponding to the positioning inputs. The icons 44, 45, 46 are respectively arranged in the form of a circle. Each icon 44, 45, 46 may have a corresponding graphical label. The corresponding graphical label can be any character, for example, a number, a letter, or a symbol. In this exemplary embodiment as shown in FIG. 1, the corresponding graphical label of the icon 44 is an alphabet letter, the corresponding graphical label of the icon 45 is an alphabet letter or a symbol, and the corresponding graphical label of the icon 46 is a number or a symbol.

The hand-held device 10 further has an indicator 34. The indicator 34 is positioned between the display 20 and the rotary wheel 30 to indicate the positioning input of the rotary wheel 30, i.e., positioning inputs corresponds to resting positions of the rotary wheel with/without rotating the rotary wheel.

The hand-held device 10 further has three switches 31, 32, 33 for selecting characters. The switches 31, 32, 33 can be any appropriate input device. For example, in the embodiment as shown in FIG. 1, the switches 31, 32, 33 are in forms of buttons. The switches 31, 32, 33 are positioned on the rotary wheel 30 as shown in FIG. 1. The switches 31, 32, 33 correspond to the character regions 41, 42, 43 respectively. Regarding the selection operation on the switches 31, 32, 33, it is described in detail below.

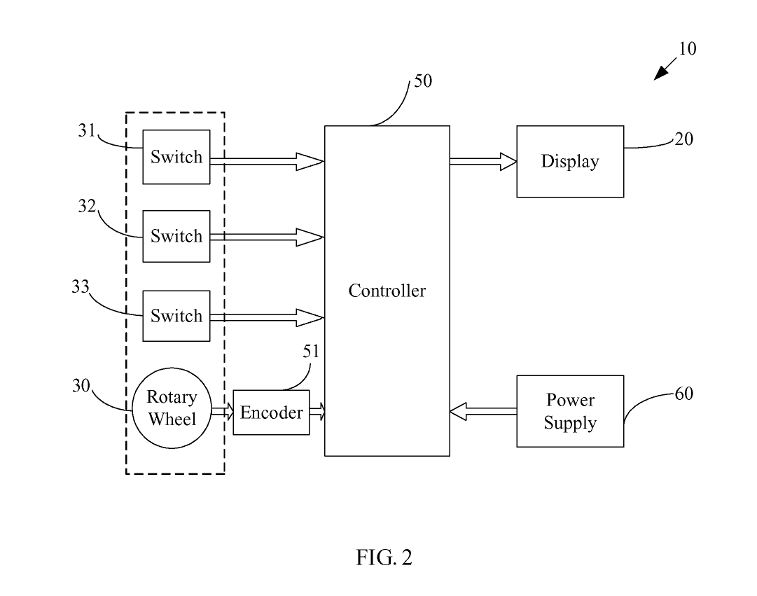

Referring to FIG. 2, a hardware infrastructure of the hand-held device 10 is disclosed. The hand-held device 10 further includes a controller 50, an encoder 51, and a memory 60. The controller 50 is connected to the switches 31, 32, 33, the encoder 51, the display 20, and the memory 60. The encoder 51 is further connected to the rotary wheel 30 and generates a positioning code corresponding to the positioning input of the rotary wheel 30. The memory 60 stores three input modes corresponding to the three character regions 41, 42, 43 respectively. Each input mode includes character codes of a character region 41, 42, 43. In response to a press input of a switch 31, switch 32, or switch 33, the controller 50 selects a character of the corresponding input mode from the memory 60 according to the positioning code the encoder 51 outputs, and sends the character to the display 20.

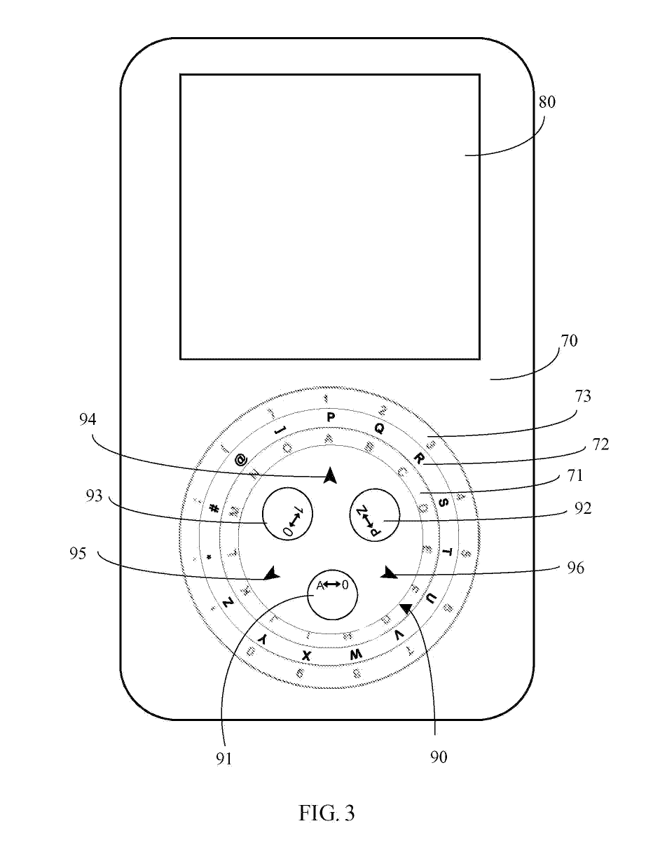

Referring to FIG. 3, a hand-held device of a second preferred embodiment according to the present invention is disclosed. The hand-held device 70 includes a display 80, three character regions 71, 72, 73, and a rotary wheel 90. The three character regions 71, 72, 73 form three circles that enclose the rotary wheel 90. The content of the character regions 71, 72, 73 is the same of the character regions 41, 42, 43. The hand-held device 70 further has three switches 91, 92, 93 for selecting characters.

The switches 91, 92, 93 can be any appropriate input device. For example, in the embodiment as shown in FIG. 3, the switches 91, 92, 93 are in form of buttons. The switches 91, 92, 93 are positioned on the rotary wheel 90 as shown in FIG. 3. The switches 91, 92, 93 correspond to the character regions 71, 72, 73 respectively. The hand-held device 70 further has three indicators 94, 95, 96 corresponding to the three character regions 71, 72, 73 respectively. The indicators 94, 95, 96 are positioned on the rotary wheel 30. The indicators 94, 95, 96 are used for selecting and inputting characters with the switches 91, 92, 93. For example, while the indicator 94 points to a character “A” of the character region 71, a press input on the switch 91 is performed, a character “A” is inputted.

Other features of the hand-held device 70 is similar to the hand-held device 10. Descriptions to them are omitted here.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A hand-held device comprising:
a rotary wheel having a plurality of positioning inputs;
a plurality of switches;
a plurality of character regions corresponding to the switches, wherein each character region comprises a plurality of icons corresponding to the positioning inputs, and each icon comprises a character; and
a controller responsive to operations on the rotary wheel and the switch for inputting a corresponding character.

2. The hand-held device of claim 1, further comprising an indicator for indicating the positioning input that the rotary wheel locates.

3. The hand-held device of claim 2, wherein the indicator is placed out of the rotary wheel.

4. The hand-held device of claim 1, further comprising three indicators.

5. The hand-held device of claim 4, wherein the indicators are placed on the rotary wheel.

6. The hand-held device of claim 1, wherein the switches are buttons.

7. The hand-held device of claim 6, wherein the buttons are placed on the rotary wheel.

8. A hand-held device comprising:
a rotary wheel having a plurality of positioning inputs;
a plurality of switches;
an encoder responsive to operations on the rotary wheel and outputting positioning codes;
a memory storing a plurality of input modes corresponding to the switches, wherein each input mode includes a plurality of characters corresponding to the positioning codes; and
a controller, wherein the controller is responsive to operations on the rotary wheel and the switch, and selects a corresponding character from the memory and inputs the character.

9. The hand-held device of claim 8, further comprising a plurality of character regions, each character region including a plurality of icons corresponding to the positioning inputs of the rotary wheel, each icon including a character.

10. The hand-held device of claim 8, further comprising an indicator to indicate the positioning input the rotary wheel locates.

11. The hand-held device of claim 10, wherein the indicator is placed out of the rotary wheel.

12. The hand-held device of claim 8, further comprising three indicators.

13. The hand-held device of claim 12, wherein the indicators are placed on the rotary wheel.

14. The hand-held device of claim 8, wherein the switches are buttons.

15. The hand-held device of claim 14, wherein the buttons are placed on the rotary wheel.
